(19) United States
(12) Patent Application Publication
(10) Pub. No.: US 2013/0122650 A1
(43) Pub. Date: May 16, 2013

(54) Method For Preparing P-Type Zinc Oxide ZnO or P-Type ZnMgO

(71) Applicant: Commissariat a l'energie atomique et aux energies alternatives, Paris (FR)

(72) Inventors: Guy Feuillet, Saint Martin D'Uriage (FR); Carole Granier, Apprieu (FR)

(73) Assignee: Commissariat a l'energie atomique et aux energies alternatives, Paris (FR)

(21) Appl. No.: 13/646,999

(22) Filed: Oct. 8, 2012

(30) Foreign Application Priority Data
Oct. 10, 2011 (FR) 11 59121

(51) Int. Cl. H01L 21/02

(52) U.S. Cl. CPC H01L 21/02694
USPC 438/104

(57) ABSTRACT

Method for preparing p-type zinc oxide ZnO or p-type ZnMgO, comprising at least the sequence of the following two steps a) and b):
a) depositing silica, optionally doped with at least one doping element from column V of the periodic table of the elements, on a surface of an n-type ZnO or n-type ZnMgO substrate;
b) annealing the substrate and the deposited silica at a sufficient temperature and for a sufficient time to induce exodiffusion of zinc from the ZnO or ZnMgO substrate to the silica, and the formation of zinc vacancies in at least one portion of the substrate adjacent to the silica; and
a step for doping said portion of the substrate adjacent to the silica and comprising the zinc vacancies with at least one doping element from column V of the periodic table of the elements during step b) or at the conclusion of step b).

### FIELD OF THE INVENTION

The invention relates to a method for preparing p-type Zinc oxide ZnO or p-type ZnMgO.

The technical field of the invention can be defined generally as being that of doping of semiconductor material.

More specifically, the technical field of the invention can be defined as being that of preparing, manufacturing p-type doped zinc oxide ZnO or ZnMgO alloy, i.e. having p-type conductivity, from non-doped ZnO or ZnMgO alloy, i.e. not having n-type intrinsic conductivity.

This p-type doping may particularly be doping with elements from column V of the periodic table of the elements, such as As, P, and optionally Sb.

Zinc oxide ZnO is a semiconductor material with numerous applications in optoelectronics, particularly in LEDs for lighting in the form of 2D thin layers and nanowires.

To produce bipolar devices, particularly near UV light-emitting diodes, which have potentially very significant industrial applications, it is necessary to carry out p-type doping of zinc oxide ZnO.

However, it is known that so-called semiconductor material doping asymmetry frequently occurs, i.e. one type of doping, e.g. n-type doping, is easier to obtain than the other type of doping, e.g. p-doping.

This specifically applies to ZnO.

### STATE OF THE RELATED ART

The preparation of p-type doped zinc oxide ZnO was difficult.

Indeed, p-type doping of ZnO always encounters significant difficulties, particularly due to the existence of intrinsic and/or extrinsic impurities causing residual n-doping of the ZnO.

The intrinsic impurities of donor type essentially consist of interstitials of the Zn cation (“Znᵢ”) and of vacancies of the oxygen anion (“V_{O}”), for which the formation energy is negative when the Fermi level Ef approaches the valence band.

On the other hand, the theory envisages that intrinsic acceptors, i.e. Zinc vacancies (“V_{Z}”) and oxygen interstitials (“Oᵢ”), have positive formation energies when, similarly, the Fermi level Ef approaches the valence band.

This involves thermodynamic equilibrium calculations.

The extrinsic impurities are essentially hydrogen, lithium and aluminium, which are very frequently found in substrates and epitaxial layers, giving rise to levels close to the conduction band.

These intrinsic and extrinsic impurities are “acceptor killers” which need to be removed when seeking to perform p-doping type of ZnO.

In the more specific case of intrinsic impurities (Znᵢ and V_{O}), one way to restrict the presence thereof consists for example of using oxygen-enriched growth conditions, both for the solid material and the epitaxial layers.

However, the growth conditions are frequently defined on the basis of considerations for obtaining the desired crystalline structure and optimising the growth surface. These growth conditions may be antinomical with conditions for adjusting the stoichiometry and ensuring material doping.

Another manner for limiting the presence of intrinsic impurities consists of moving away, differing from thermodynamic equilibrium conditions.

In this way, the document by Tsukazaki et al. Nat, Mat. 4, 42, 2005 describes a method wherein layers of ZnO undergo epitaxial growth by alternating low-temperature cycles to ensure the incorporation of the nitrogen dopant, and high-temperature cycles to enhance the growth front and the layer crystallinity.

P-doping in the region of 10^{E}16 was thus performed and light-emitting p/n junctions were obtained.

However, this method is based on the use of the nitrogen dopant in an oxygen site, with a high activation energy, i.e. in the region of 260 meV to 1.4 eV based on the various theoretical estimations.

Therefore, this method produces low hole densities at room temperature. Furthermore, the lack of stability of nitrogen in the ZnO matrix and the very likely formation of diatomic nitrogen N₂ mean that it is unlikely to product stable devices over time using this p-doping method.

Therefore, it is necessary to try to use other acceptors with a lower activation energy to create more holes and ensure that the future p-n junction would not be subject to disequilibrium, resulting in excess electron injection phenomena through the p-n junction without radiative recombination.

This rules out, in principle, the other V elements for oxygen substitution, for which the formation energies are high and the ionisation energies are even greater than those of nitrogen.

For example, this ionisation energy is 900 meV for phosphorus and 1.5 eV for arsenic are mentioned in the document by Ü özgur et al., Journal of Appl. Phys., 98, 041301 (2005) and in the document by C. H. Park, S. B. Zhang, and S.-H. Wei, Phys. Rev. B 66, 073202 (2002).

On the other hand, the theory, set forth for example in the document by Limpijumnong, S. B. Zhang, S. H. Wei, and C. H. Park, Phys. Rev. Lett. 92, 155504 (2004) envisages that the acceptor complexes associating cation vacancies and column V elements such as P, As and Sb, for Zn substitution have lower ionisation energies, typically in the region of 150-160 meV.

The complexes in question in this instance are of (2V_{Zn}, As_{Zn}) or (2V_{Zn}, P_{Zn}) type.

This is supported by the experimental data.

In this way, the document by Ryu et al., Appl. Phys. Lett. 83, 87(2003), the document by Allenic et al., J Phys. D 2008, and more recently the document by B. J. Kim et al. , Appl. Phys. Lett. 94, 103506 (2009), propose activation energies in the region of 120 meV for arsenic.

These ionisation energies are then sufficiently low to induce a hole density suitable for preventing excess electron injection at the junction.

However, in order to be effective, this p-doping method, by forming acceptor complexes associated with Zn vacancies, not only requires that n-type residual impurities, i.e. V_{O} and Znᵢ, be minimised, as much as possible, but also that vacancies of said cation be actually present.

Indeed, it is known (see for example the document by A. Zunger , Appl. Phys. Lett. 83 No. 1, 2003 and the document by A. Janotti and C. G. Van de Walle Rep. Prog. Phys. 72 (2009) 126501), as mentioned above, that Zn vacancy formation energies are positive when the Fermi level approaches the valence band.

Since the complexes herein in question involve three Zn vacancies, it is easily understood that the formation thereof will be very difficult in terms of energy.

For a clearer understanding of the situation, reference may be made to FIG. 1 in the document by A. Janotti and C. G. Van de Walle, Rep. Prog. Phys. 72 (2009) 126501, giving the formation energies calculated for the various types of intrinsic, native defects, in ZnO, based on the position of the Fermi level and for “O-enriched” or “Zn-enriched” conditions.

In conclusion, the methods used to date to perform p-doping of ZnO consist of setting up oxygen-rich conditions during growth or performing post-growth processing in an oxygen atmosphere. Doping in the region of 10^{E}17/cm³ was thus obtained.

However, as mentioned above, the growth conditions are frequently defined accounting for considerations in respect of obtaining the desired crystalline structure and optimising the surface. These conditions are not always and even frequently the conditions promoting Zn vacancies formation.

Therefore, in respect of the above, there is still an unfulfilled need for a method for preparing p-type zinc oxide ZnO suitable for efficient ZnO doping.

There is also a need for a method for preparing p-type Zinc oxide ZnO which is simple and reliable.

More specifically, there is a need for a method for preparing p-type zinc oxide ZnO wherein, prior to the p-type doping, the residual intrinsic n-type impurities such as oxygen vacancies V_{O} and zinc interstitials of ZnO are removed or at least minimised and zinc vacancies are created such that subsequently efficient p-type doping by forming acceptor complexes binding zinc vacancies and doping elements from column V of the periodic table of the elements can be performed.

The goal of the present invention is that of providing a method for preparing p-type zinc oxide ZnO meeting all the needs mentioned above.

A further goal of the present invention is that of providing a method for preparing p-type zinc oxide ZnO not involving the drawbacks, defects, limitations and disadvantages of the methods according to the prior art and providing solving the problems of the methods according to the prior art.

### DESCRIPTION OF THE INVENTION

This aim and others are achieved, according to the invention by means of a method for preparing p-type zinc oxide ZnO or p-type ZnMgO, comprising at least the sequence of the following two steps a) and b):

a) depositing silica, optionally doped with at least one doping element from column V of the periodic table of the elements, on a surface of an n-type ZnO or n-type ZnMgO substrate;

b) annealing the substrate and the deposited silica at a temperature sufficient and for a time sufficient to induce exodiffusion of zinc from the ZnO or ZnMgO substrate to the silica, and the formation of zinc vacancies in at least one portion of the substrate adjacent to the silica; and

a step for doping said portion of the substrate adjacent to the silica and comprising the zinc vacancies with at least one doping element from column V of the periodic table of the elements during step b) or following step b).

According to the invention, the term n-type ZnO or n-type ZnMgO means that the ZnO or ZnMgO intrinsically exhibits n-type conductivity, i.e. the ZnO or ZnMgO has not been intentionally or voluntarily n-type doped but exhibits said n-type conductivity intrinsically, inherently.

This type of non-intentionally or non-voluntarily n-type doped ZnO or ZnMgO is also referred to using the terms non (intentionally) doped ZnO or ZnMgO.

Advantageously, the n-type ZnO or n-type ZnMgO substrate may be in the form of a monolithic solid substrate, of a layer, for example, an epitaxial layer, of at least one nanowire or of a ZnO quantum well heterostructure.

Advantageously, the substrate may be in the form of an heterostructure of ZnO quantum well in ZnMgO alloy layers with a bottom layer made of n-type doped ZnMgO and a top layer made of non-doped ZnMgO on the top face whereof the silica is deposited.

Advantageously, the doping element from column V of the periodic table of the elements may be selected from P, As and Sb.

Advantageously, the silica may be deposited in the form of a layer, the thickness of said layer being preferably from 50 to 500 nm, or more preferably from 100 to 500 nm.

Advantageously, during step b), annealing is performed at a temperature of 400° C. to 1000° C., preferably from 600° C. to 950° C., more preferably from 700° C. to 800° C., for a time of 30 min to 15 hours.

Advantageously, said portion of the substrate adjacent to the silica extends over a thickness of 50 to 500 nm from an interface between the silica and ZnO or ZnMgO.

This thickness is generally equivalent to the thickness of the future p-zone to be created in the substrate.

Advantageously, the doping of said portion of the substrate adjacent to the silica with at least one doping element from column V of the periodic table of the elements is performed by diffusion or by implantation of said element.

The method according to the invention comprises a specific sequence of specific steps never hitherto described or suggested in the prior art.

In particular, the specific sequence of steps a) and b) has never been hitherto described or suggested in the prior art.

The method according to the invention meets, among others, the needs listed above and achieves the goals mentioned above.

The method according to the invention does not involve the drawbacks of the methods according to the prior art and provides a solution to the problems of the methods according to the prior art.

The method according to the invention is suitable for promoting the formation of acceptor complexes in ZnO, which, as mentioned above, have a sufficiently low activation energy, i.e. in the region of 120-160 meV, to ensure strong activation of the dopants introduced during doping, whether the doping is performed using an implantation doping method or a diffusion doping method.

It should be noted that these acceptor complexes bind the zinc vacancies and the elements from column V of the periodic table of the elements positioned on these zinc vacancies.

So as to promote the formation of these complexes, the method according to the invention starts first of all, during steps a) and b), with promoting significantly the formation of zinc vacancies in ZnO.

During these steps a) and b), besides the formation of zinc vacancies, the method according to the invention also removes zinc interstitials, which are residual donors representing a limiting factor for p doping.

The method according to the invention is then based on incorporating in the ZnO, during step b) or at the conclusion of step b), doping elements from column V, which occupy some vacant Zn sites.

This incorporation or doping may be performed particularly by means of ex-situ methods of the diffusion or implantation type. It was demonstrated, according to the invention, that ZnO on the one hand and silica SiO₂ on the other hand “interact” strongly and that the interdiffusion phenomena at the interfaces thereof are easy.

The secondary ion mass spectrometry analyses (“SIMS”) (see FIG. 1 for a phosphorus-doped silica deposit and see FIG. 2 for an arsenic-doped silica deposit), in particular, conducted by the inventors, demonstrate that zinc has a strong tendency to diffuse to SiO₂ when said SiO₂ is deposited on ZnO and annealing is performed, at a sufficient temperature and for a sufficient time, preferably at temperatures of between 700° C. and 800° C. for times of 30 min to 15 hours. Also, by means of X-ray powder diffraction analysis, the formation of a crystalline zinc silicate phase, Zn₂SiO₄, at the interface between ZnO and SiO₂, after annealing of a SiO₂ deposit on ZnO is demonstrated.

These silicates are well-known and are the result of the interaction between SiO₂ and numerous metal oxides.

These observations are in agreement with the very low values found in the literature, for autodiffusion activation energies of Zn interstitials: typically in the region of 0.2-0.3 eV, as mentioned in the document by Erhart et al., Appl. Phys. Lett. 88, (2006), 201918.

The diffusion of these interstitials thus occurs at low temperature compared to those that would allow the diffusion of oxygen vacancies, for which the autodiffusion activation energy is higher, i.e. in the region of 2 eV.

The “SIMS” measurements demonstrate that there is no diffusion of oxygen to the SiO₂ deposited on the ZnO surface.

It can thus be inferred that silica is a barrier to oxygen exodiffusion, whereas it enables that of zinc.

This thus gives rise to a material with oxygen-rich and Zn-poor stoichiometry over a depth of some hundred nm, for example from 50 to 500 nm under the SiO₂/ZnO interface.

The method according to the invention, due to the formation of a zinc-rich crystalline phase between the ZnO and SiO₂, thus makes it possible for the first time to solve the problem linked with the high energy required for forming Zn vacancies in ZnO which makes the formation of the complexes mentioned above difficult or even impossible.

The method according to the invention, particularly by means of the sequence of steps a) and b) comprised therein, provides for the first time a solution to this hitherto insurmountable problem.

The ZnO material obtained at the conclusion of steps a) and b) of the method according to the invention sees the stoichiometry thereof offset and is thus liable to be more suitable for p-type doping by means of the formation of acceptor complexes with a low activation energy, associating Zn vacancies and acceptor elements from column V of the periodic table of the elements such as As, P and optionally Sb on a Zn site, as already specified above.

It should be noted that most ZnO crystals and epitaxial layers are obtained under zinc-rich conditions, inducing the presence of oxygen vacancies and Zn interstitials, which are intrinsic impurities which donor properties are redhibitory for obtaining p-doping. This Zn-enriched stoichiometry is governed by the growth method per se.

In sum, it is known generally that doping impurities should be positioned on a given site of the crystalline lattice or involve complexes between these impurities and native defects such as interstitials or vacancies.

The method according to the invention specifically makes it possible to create the native defects required to facilitate either the insertion of the doping impurity on a crystalline lattice site, in the crystal lattice cell, or the formation of complexes of the impurity with ZnO vacancies.

The method according to the invention is based on the creation of these native defects by forming a stable new crystalline phase at the interface between ZnO and another material, i.e. the silica deposited on ZnO generally in the form of a layer.

This new phase shifts the stoichiometry of the underlying layer and makes it possible to create the native defects required.

The method according to the invention enables the formation of Zn vacancies in the ZnO, and the exodiffusion of Zn interstitials from the ZnO to the silica, and subsequently or simultaneously the insertion in the ZnO lattice cell of a doping element from column V of the periodic table of the elements or the creation of low activation energy complexes of this doping element with the vacancies.

The elements from column V of the periodic table of the elements may be introduced into the ZnO, by diffusion or by implantation.

According to a first embodiment of the method according to the invention, the following successive steps are performed:
depositing silica, doped with at least one doping element from column V of the periodic table of the elements, on a surface of an n-type ZnO or n-type ZnMgO substrate;
annealing the substrate and the deposited silica at a sufficient temperature and for a sufficient time to induce exodiffusion of the zinc from the ZnO or ZnMgO substrate to the silica, and the formation of zinc vacancies in at least one portion of the substrate adjacent to the silica; and simultaneously diffusing the element from column V of the periodic table of the elements to said portion of the substrate adjacent to the silica and comprising Zn vacancies.

Advantageously, annealing is performed at a temperature of 700° C. to 800° C., for a time of 30 min to 15 hours, preferably in an oxygen atmosphere or air.

According to a second embodiment of the method according to the invention, the following successive steps are performed:
depositing non-doped silica on a surface of an n-type ZnO or n-type ZnMgO substrate;
annealing the substrate and the deposited silica at a sufficient temperature and for a sufficient time to induce exodiffusion of zinc from the ZnO or ZnMgO substrate to the silica, and the formation of zinc vacancies in at least one portion of the substrate adjacent to the silica;
implanting at least one doping element from column V of the periodic table of the elements through the silica in said portion of the substrate adjacent to the silica and comprising zinc vacancies;
annealing the substrate implanted with doping elements to remove the implantation defects and activate the doping elements (i.e. position said doping elements in the correct site).

Implantation is advantageously performed at room temperature (generally 20° C. to 25° C.), for a total implanted dose between 10^{E}13 and 10^{E}15 at/cm², and an energy between 50 and 200 keV.

Advantageously, in this second embodiment of the method according to the invention, annealing is performed at a temperature of 700° C. to 900° C., for a time of 15 min to 2 hours, preferably in an oxygen atmosphere or air.

According to a third embodiment of the method according to the invention, the following successive steps are performed:
depositing non-doped silica on a surface of an n-type ZnO or n-type ZnMgO substrate;
annealing the substrate and the deposited silica at a sufficient temperature and for a sufficient time to induce exodiffusion of zinc from the ZnO or ZnMgO substrate to the silica, and the formation of zinc vacancies in at least one portion of the substrate adjacent to the silica;
removing the silica;
diffusing at least one doping element from column V of the periodic table of the elements in said portion of the substrate adjacent to the silica and comprising zinc vacancies;
optionally activation annealing the dopants in the substrate wherein the dopant element has diffused.

The activation annealing is, in this instance, optional, since it is possible that the diffusion is performed at temperatures suitable for positioning the dopant at the right place (activating same), but otherwise, activation post-annealing is required.

Advantageously, in this third embodiment of the method according to the invention, the silica is removed by means of a reactive ion etching (RIE) method or by means of a chemical etching method.

Advantageously, in this third embodiment of the method according to the invention, the diffusion of at least one doping element from column V of the periodic table of the elements, such as arsenic or phosphorus, is performed using a solid or vapour source of said doping element or of a compound containing said doping element.

For example, diffusion of As in ZnO is typically effective from 500° C.

For example, the compound containing arsenic is GaAs.

Advantageously, in this third embodiment of the method according to the invention, the optional activation annealing of the dopants of the substrate wherein the doping element diffusion is performed by means of a treatment at a temperature of 700° C. to 900° C. for a time of 15 min to 2 hours, preferably in an oxygen atmosphere or air.

This activation annealing may also be performed by means of rapid thermal annealing (RTA) at a temperature of 700° C. to 800° C. and for a time of 10 to 300 seconds.

The p-type doped ZnO or ZnMgO prepared using the method according to the invention may particularly be in the form of a thin layer, particularly a 2D thin layer, for example 50 nm to 500 nm thick, for example 50 to 100 nm.

This thin layer, particularly this 2D thin layer, of p-type doped ZnMgO may constitute a surface layer of an n-type monolithic solid substrate and, in this case, it is generally rather 50 to 500 nm thick.

In the case of nanowires, this thin layer may be found on the top portion of the nanowires over a thickness generally of 50 to 500 nm and/or on the lateral, side, portion over a thickness generally of 50 to 100 nm.

Indeed, the n-type doped ZnO or ZnMgO subjected to the method according to the invention may be in the form of a substrate for example of a monolithic solid substrate, and which it undergoes the method according to the invention, a surface layer of this substrate, for example this monolithic solid substrate, is converted into p-type doped ZnO or ZnMgO, respectively. This surface layer generally has the thickness mentioned above, i.e. 50 to 500 nm thick.

The substrate may be in the form of n-type nanowires and when it undergoes the method according to the invention, a surface layer of these nanowires on the top portion and/or the lateral, side, portion of the nanowires is converted into p-type doped ZnO or ZnMgO, respectively.

This surface layer is generally 50 to 500 nm thick on the top portion of the nanowires, and generally 50 to 100 nm on the lateral, side, portion of the nanowires.

The invention is particularly applicable for preparing a substrate, or structure, for example a monolithic, solid, substrate, or nanowires, made of n-type (non-intentionally doped) ZnO or ZnMgO wherein a surface layer has been converted into p-type doped ZnO or ZnMgO, respectively, using the method according to the invention as described above.

The surface layer converted into p-type doped ZnO or ZnMgO is generally 100 nm to 500 nm thick, for example 50 nm to 100 nm.

Such a compact integral structure exhibits thickness between 100 nm and 500 nm. Such properties had not hitherto been obtained in the prior art.

The method according to the invention thus makes it possible to create acceptors exhibiting different optical and electrical properties over a given thickness from an n-type non (intentionally) doped ZnO or ZnMgO substrate, for example an n-type non (intentionally) doped ZnO or ZnMgO monolithic substrate, or n-type non (intentionally) doped ZnO or ZnMgO nanowires.

In this way, it is easy to prepare by means of a simple method, and directly from a simple monolithic substrate or nanowires, a p-n type junction without applying multiple growing steps for example.

Furthermore, the invention finds its use in heterostructure of ZnO quantum wells in ZnMgO alloy layers with a bottom layer of n-type doped ZnMgO and an top layer of non-doped ZnMgO converted into p-type ZnMgO using the method according to the invention.

The invention finds also its use in an optoelectronic device comprising p-type doped ZnO or ZnMgO prepared using the method according to the invention where the substrate, made of (non-intentionally) n-type doped ZnO or ZnMgO wherein a surface layer has been converted into p-type doped ZnO or p-type doped ZnMgO respectively using the method according to the invention or the quantum wells heterostructure described above.

This electronic device may particularly be a light-emitting diode (LED), particularly a UV LED.

The p-type doped ZnO or ZnMgO prepared using the method according to the invention or the substrate described above or the heterostructure described above may particularly be used in optoelectronics.

The invention will be understood more clearly on reading the detailed description hereinafter, particularly with reference to the preferred embodiments of the method according to the invention.

This detailed description given for illustrative and non-limiting purposes, refers to the attached drawings wherein:

### BRIEF DESCRIPTION OF THE DRAWINGS

FIG. 1 is a graph showing the SIMS analyses conducted on a ZnO substrate whereon phosphorus-doped silica is deposited having undergone annealing at a temperature of 700° C. or at a temperature of 800° C. for 5 hours or 15 hours.

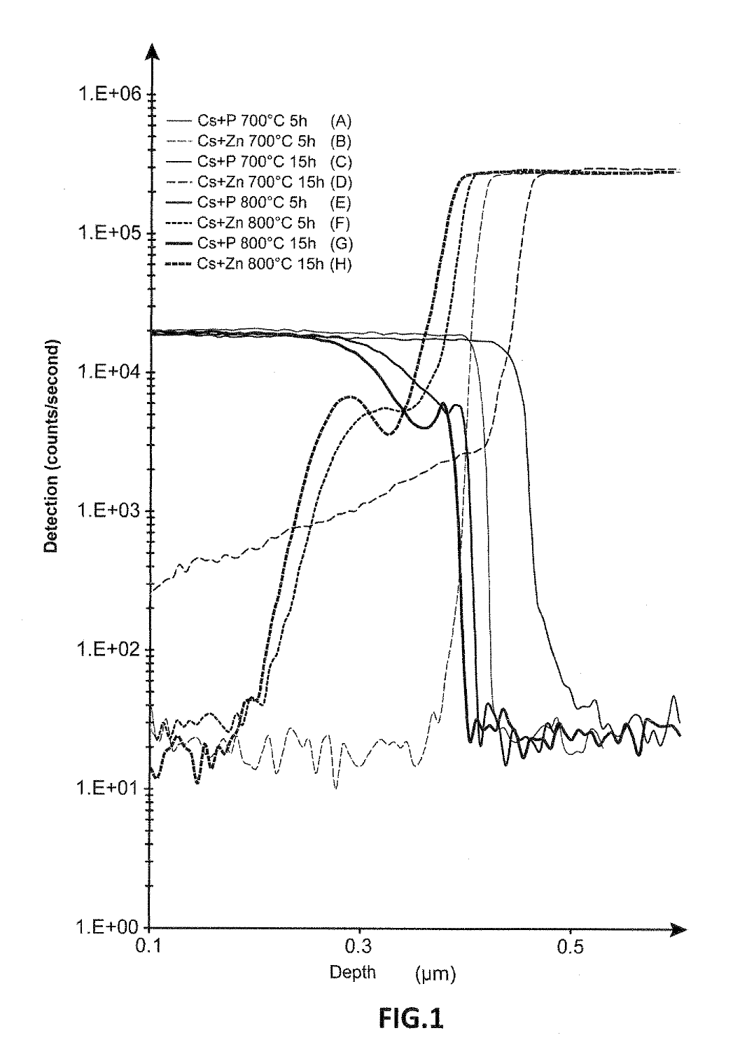

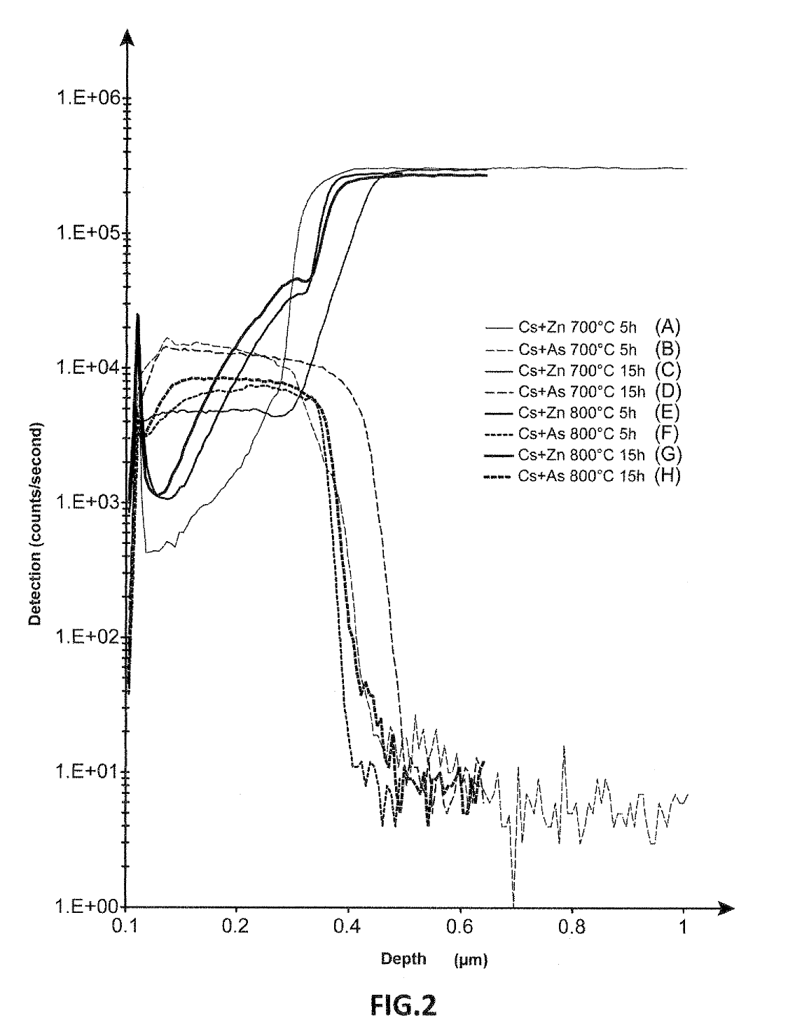

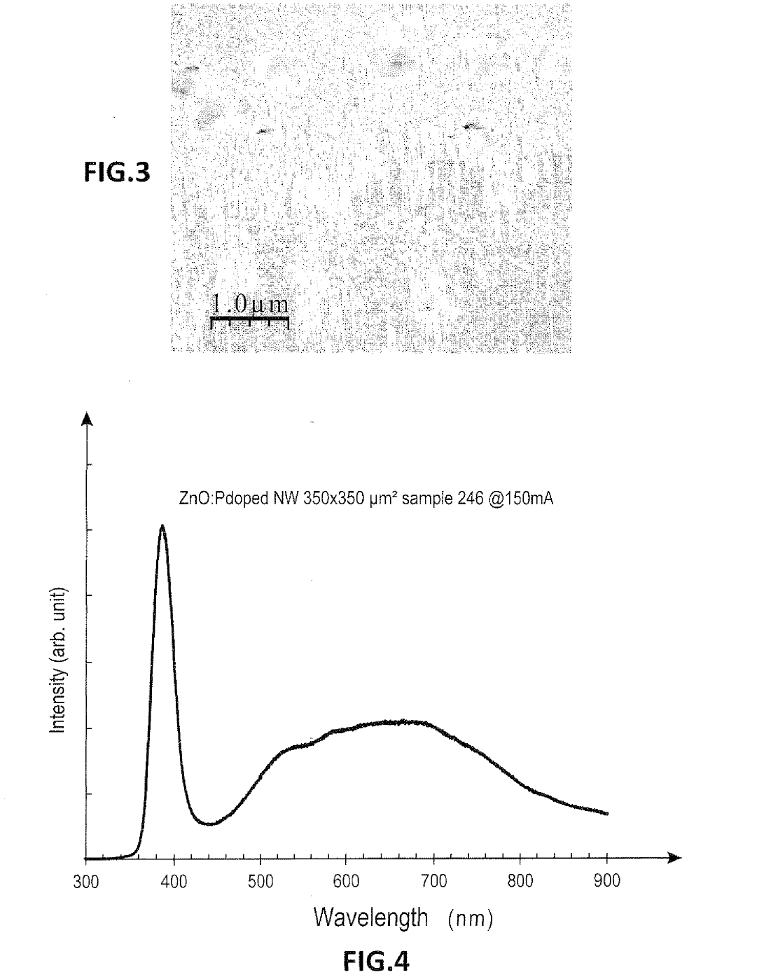

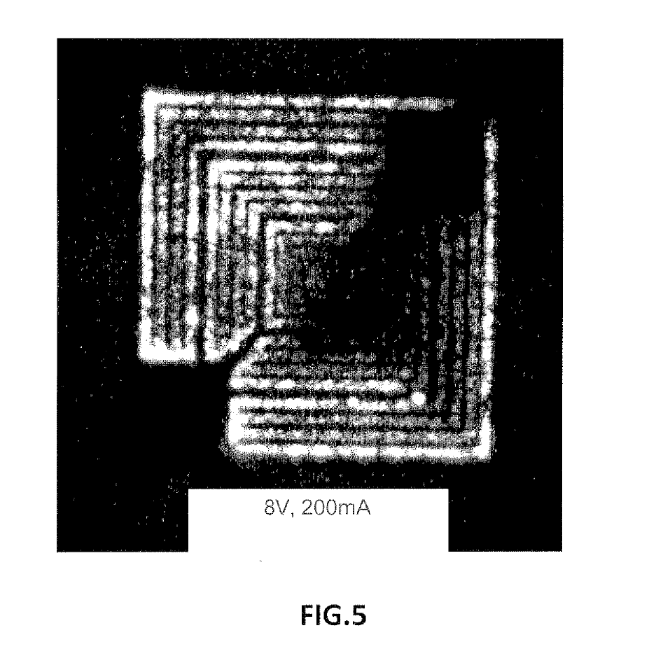

It should be noted that, in FIG. 1 (and in FIG. 2), the notations Cs+P, Cs+Zn and Cs+As are used, since in SIMS, primary ions and secondary ions are associated, in this instance caesium for electronegative elements such as P, Zn, or As.

Curve A is the SIMS analysis for phosphorus conducted on a substrate having undergone annealing at a temperature of 700° C. for 5 hours.

Curve B is the SIMS analysis for zinc conducted on a substrate having undergone annealing at a temperature of 700° C. for 5 hours.

Curve C is the SIMS analysis for phosphorus conducted on a substrate having undergone annealing at a temperature of 700° C. for 15 hours.

Curve D is the SIMS analysis for zinc conducted on a substrate having undergone annealing at a temperature of 700° C. for 15 hours.

Curve E is the SIMS analysis for phosphorus conducted on a substrate having undergone annealing at a temperature of 800° C. for 5 hours.

Curve F is the SIMS analysis for zinc conducted on a substrate having undergone annealing at a temperature of 800° C. for 5 hours.

Curve G is the SIMS analysis for phosphorus conducted on a substrate having undergone annealing at a temperature of 800° C. for 15 hours.

Curve H is the SIMS analysis for zinc conducted on a substrate having undergone annealing at a temperature of 800° C. for 15 hours.

The y-axis shows the detection (in counts/second) and the x-axis the depth with respect to the SiO₂ surface in μm.

FIG. 2 is a graph showing the SIMS analyses conducted on a ZnO substrate whereon arsenic-doped silica is deposited having undergone annealing at a temperature of 700° C. or at a temperature of 800° C. for 5 hours or 15 hours.

Curve A is the SIMS analysis for zinc conducted on a substrate having undergone annealing at a temperature of 700° C. for 5 hours.

Curve B is the SIMS analysis for arsenic conducted on a substrate having undergone annealing at a temperature of 700° C. for 5 hours.

Curve C is the SIMS analysis for zinc conducted on a substrate having undergone annealing at a temperature of 700° C. for 15 hours.

Curve D is the SIMS analysis for arsenic conducted on a substrate having undergone annealing at a temperature of 700° C. for 15 hours.

Curve E is the SIMS analysis for zinc conducted on a substrate having undergone annealing at a temperature of 800° C. for 5 hours.

Curve F is the SIMS analysis for arsenic conducted on a substrate having undergone annealing at a temperature of 800° C. for 5 hours.

Curve G is the SIMS analysis for zinc conducted on a substrate having undergone annealing at a temperature of 800° C. for 15 hours.

Curve H is the SIMS analysis for arsenic conducted on a substrate having undergone annealing at a temperature of 800° C. for 15 hours.

The y-axis shows the detection (in counts/second) and the x-axis the depth with respect to the SiO₂ surface in μm.

FIG. 3 is an image obtained during Atomic Force Microscopy (AFM), in Scanning Capacitance Microscopy (SCM) mode, of a nanowire assembly encapsulated in P-doped silica, and after annealing at 800° C. for 5 hours.

The scale shown in FIG. 3 is 1.0 μm.

FIG. 4 is the electroluminescence spectrum of a set of ZnO nanowires doped in the top portion thereof by diffusion from a phosphorus-doped silica, using the method according to the invention.

The x-axis shows the wavelength (in nm), and the y-axis the intensity (arbitrary units, arb. unit);

FIG. 5 is a photograph showing the optical emission of a light-emitting diode having nanowires doped by diffusion in the top portion thereof.

### DETAILED DESCRIPTION OF PARTICULAR EMBODIMENTS

In a first step a) of the method for preparing p-type zinc oxide ZnO or p-type ZnMgO according to the invention, silica, optionally doped with at least one doping element from column V of the periodic table of the elements is deposited on a surface of a n-type ZnO or n-type ZnMgO substrate.

The ZnO or ZnMgO substrate may be in the form of a thin layer, particularly a “2D” thin layer generally 200 nm to 1 μm thick, or of a monolithic “solid” substrate, or in the form of nanowires.

The dimensions of the monolithic “solid” substrate may be generally the dimensions of commercially available substrates of this type, with a diameter for example of 20 mm to 50.8 mm (2 inches) and a thickness of approximately 500 μm.

The “2D” layer is generally prepared using an epitaxial growth method on a substrate generally made of Al₂O₃, of silicon or of any other material suitable for epitaxial growth of ZnO.

Preferentially, the epitaxial layers are deposited on a ZnO solid substrate to obtain epitaxial layers free from crystalline defects and thus homogeneous distribution of the dopants in the material.

The solid substrate is generally obtained from monocrystalline ingots obtained using a hydrothermal growth method or any other crystal generation technique known to the man skilled in the art.

The ZnO nanowires may be prepared on any type of crystalline or polycrystalline or even polymeric support.

The nanowires may be deposited using so-called self-organisation techniques or on suitably etched substrates to induce localised and ordered growth of said nanowires. The typical dimensions thereof are 50 to 300 nm in diameter and 1 to 5 μm in height.

It should be noted that most ZnO solid substrates, crystals, and epitaxial layers, and nanowires are obtained under zinc-rich conditions, inducing the presence of oxygen vacancies and Zn interstitials, which are intrinsic impurities with redhibitory donor properties for obtaining p-doping. This Zn-rich stoichiometry is governed by the growth method per se.

Otherwise, the substrate may be in the form of a ZnO quantum wells heterostructure.

Such a heterostructure generally comprises ZnO quantum wells in ZnMgO alloy layers, barriers, for example 1 to 5 layers or barriers.

This heterostructure may be two-dimensional in the case of epitaxial layers or may be included in nanowires deposited on a specific substrate. In the latter case, the heterostructure may be referred to as axial if the stack of successive layers is made along the axis of the nanowires or radial if the stack of layers forming the heterostructure is grown laterally from the initial ZnO nanowires.

The heterostructure comprises a bottom layer or barrier of n-type doped ZnMgO and a top layer or barrier of non-doped ZnMgO on the top face whereof the silica is deposited according to the method according to the invention.

Using the method according to the invention with such substrates in the form of previously constituted heterostructures, it is thus possible to form the p-doped portion of a light-emitting device easily, however provided that the annealing temperatures in question are not liable to induce interdiffusion at the quantum wells interfaces.

Typically, the literature refers to quantum wells heterostructures deposited at temperatures of approximately 800° C., without the appearance of interdiffusion phenomena at the interfaces between the ZnMgO and the ZnO quantum wells (A. Lusson, J. V ac. Sci. Technol. B, 27(3), 1755, 2009), that is thus compatible with the annealing temperatures that can be used for inducing the formation of Zn vacancies under the SiO₂.

According to the method according to the invention in step a) thereof, silica, optionally doped with at least one doping element from column V of the periodic table of the elements is deposited on at least one surface of the ZnO sample, substrate.

The silica deposit may take different forms.

This deposit may particularly take the form of a silica layer, preferably deposited on the top surface of the “2D” layer or on one of the surfaces of the solid substrate, preferably on the top surface of the solid substrate.

This deposition may also be carried out conventionally about nanowires, i.e. on the top portion thereof and on the lateral portion thereof.

This layer may be 50 to 500 nm thick, preferably 100 to 500 nm.

The silica may be deposited by means of any suitable technique, for example by means of spin-coating, or by means of physical vapour deposition.

In the case of the first preferred embodiment of the method according to the invention, the deposited silica is doped with at least one doping element from column V of the periodic table of the elements.

The dopant content of the deposited silica is generally 1% to 5%.

The doping element from column V of the periodic table of the elements is generally selected from P, As and Sb.

The next step b) of the method according to the invention is a step for annealing the substrate and the silica deposited during step a).

According to the invention, this annealing is performed at a sufficient temperature and for a sufficient time to induce exodiffusion of zinc from the ZnO or ZnMgO substrate to the silica, and the formation of zinc vacancies in at least one portion of the substrate.

This portion of the substrate is generally in the form of a layer for example 50 to 500 nm thick, preferably 50 to 100 nm, from the interface between the silica and the ZnO or ZnMgO substrate. This thickness is generally equivalent to the thickness of the future p-zone to be created in the substrate.

The depth for which the material becomes p-type is closely dependent on the exodiffusion conditions, thus on the annealing temperature and times.

The annealing temperature is generally from 400° C. to 1000° C., preferably from 600° C. to 950° C., more preferably from 700° C. to 800° C.

Similarly, the time for which the annealing in step b) is performed can be easily determined by the man skilled in the art, and is also dependent particularly on the nature and size of the ZnO sample.

This time is generally from 30 min to 15 hours. In the case which is that of the first embodiment when a layer of silica doped with a doping element from column V of the periodic table of the elements is deposited, then the annealing conditions, temperature and time are selected so as also to enable the diffusion of the dopant from the SiO₂ to the ZnO and the incorporation of the dopant on the zinc sites which become vacant. These conditions will be described in more detail hereinafter in the detailed description of the first preferred embodiment of the method according to the invention.

This annealing step may be performed in an oxygen atmosphere or in air, for example ambient air.

The method according to the invention, besides the specific sequence of steps a) and b) described above, comprises a step for doping the substrate with at least one doping element from column V of the periodic table of the elements.

This doping step may be performed during step b), simultaneously with step b), or following step b).

The doping may be performed by means of any method known to the man skilled in the art, for example by implanting at least one ion of a doping element or by diffusing a doping element from a solid or vapour source.

In a first preferred embodiment of the method according to the invention, the following successive steps are performed:
depositing silica, doped with at least one doping element from column V of the periodic table of the elements, on a surface of an n-type ZnO or n-type ZnMgO substrate;
annealing the substrate and the deposited silica at a sufficient temperature and for a sufficient time to induce exodiffusion of zinc from the ZnO or ZnMgO substrate to the silica, and the formation of zinc vacancies in at least one portion of the substrate; and simultaneously diffusion of the doping element from column V of the periodic table of the elements to the Zn vacancies.

The deposition of the doped silica is generally carried out as already described above in a general way.

This first preferred embodiment of the method according to the invention may be considered to be the simplest, preferred embodiment, of the method according to the invention.

Indeed, it consists of depositing, on the ZnO surface, silicas doped with the element to be used for the p-doping of the ZnO, for example P, As or Sb.

The annealing conditions, particularly the temperature and time, are selected, in this first embodiment, not only so as to induce the exodiffusion of Zn and the formation of zinc vacancies in the ZnO as in the broadest embodiment of the method according to the invention, but also to simultaneously enable the diffusion of the dopant, for example P, As, or Sb from the SiO₂ to the zinc vacancies created in the ZnO and the incorporation thereof on the Zn sites which have thus become vacant.

The annealing conditions, particularly the temperature and time, are those already described above in a general way for step b). Indeed, the annealing conditions such as temperature, time, atmosphere, etc. for a doped silica layer with diffusion of the dopant from the silica into the ZnO are generally equivalent to those for annealing with a non-doped silica layer.

In a second preferred embodiment of the method according to the invention, the following successive steps are performed:
depositing non-doped silica on a surface of an n-type ZnO or n-type ZnMgO substrate;
annealing the substrate and the deposited silica at a sufficient temperature and for a sufficient time to induce exodiffusion of zinc from the ZnO or ZnMgO substrate to the silica, and the formation of zinc vacancies in at least one portion of the substrate;
implanting at least one doping element from column V of the periodic table of the elements through the silica in said portion of the substrate;
optional annealing to activate the substrate implanted with the doping elements.

In this second preferred embodiment of the method according to the invention, the deposition step a) and annealing step b) are performed as described in the most general case.

The silica is generally deposited in the form of a layer, the thickness whereof is generally as already described above.

The annealing is merely performed at a sufficient temperature and for a sufficient time to induce exodiffusion of zinc from the ZnO or ZnMgO substrate to the silica, and the formation of zinc vacancies in at least one portion of the substrate.

As already described above, these sufficient temperatures and time may be determined easily by the man skilled in the art.

This temperature is generally 400° C. to 1000° C., preferably 600° C. to 950° C., more preferably 700° C. to 800° C. and this time is generally 30 minutes to 15 hours.

At the end of the annealing, the oxygen-rich material may then be doped by means of ion implantation through the silica layer with elements from column V of the periodic table of the elements such as As, P or Sb.

The conditions for this implantation may be determined easily by the man skilled in the art.

Implantation is advantageously performed at room temperature, for total implanted doses between 10^{E}13 and 10^{E}15 at/cm², and energies between 50 and 200 keV.

This implantation is followed by implantation annealing to position the dopant atoms on the vacant Zn sites and activate the dopants.

The conditions for this annealing, referred to as implantation annealing, may be determined easily by the man skilled in the art. This implantation annealing is generally performed at a temperature of 700° C. to 900° C. for 15 minutes to 2 hours, in an oxygen atmosphere or in air.

Unlike diffusion, implantation makes it possible to adjust the profile according to the concentration depth of the element to be used for doping.

The post-implantation annealing, by leaving the layer of SiO₂ on the surface of the substrate, may promote the formation of Zn vacancies and thus that of acceptor complexes.

In a third preferred embodiment of the method according to the invention, the following successive steps are performed:
depositing non-doped silica on a surface of an n-type ZnO or n-type ZnMgO substrate;
annealing the substrate and the deposited silica at a sufficient temperature and for a sufficient time to induce exodiffusion of zinc from the ZnO or ZnMgO substrate to the silica, and the formation of zinc vacancies in at least one portion of the substrate;
removing the silica;
diffusing at least one doping element from column V of the periodic table of the elements in said portion of the substrate;
optionally annealing to activate the dopants in the substrate wherein the doping element has diffused.

In this third preferred embodiment of the method according to the invention, the deposition step a) and annealing step b) are performed as described above in the most general case.

The silica is generally in the form of a layer, the thickness whereof is generally as already described above.

The annealing is merely performed at a sufficient temperature and for a sufficient time to induce exodiffusion of zinc from the ZnO or ZnMgO substrate to the silica, and the formation of zinc vacancies in at least one portion of the substrate.

As already described above, these sufficient temperatures and time may be determined easily by the man skilled in the art.

This temperature is generally from 400° C. to 1000° C., preferably from 600° C. to 950° C., more preferably from 700° C. to 800° C. and this time is generally from 30 minutes to 15 hours.

Following annealing, the silica, generally in the form of a layer, is removed, eliminated.

The silica may be eliminated, removed by means of any suitable method known to the man skilled in the art.

The silica may be removed or eliminated by means of a dry etching process or by means of a wet chemical etching process.

Preferably, a dry etching process such as reactive ion etching (RIE) is used.

After eliminating or removing the silica, for example in the form of a layer, the diffusion of at least one doping element from column V of the periodic table of the elements is performed in said portion of the substrate wherein zinc vacancies have been created and which is, for this reason, oxygen-rich.

In other words, the diffusion of at least one doping element from column V of the periodic table of the elements such as As, or P, or Sb is performed on the oxygen-rich surface created at the end of the annealing.

This diffusion may be performed by means of a solid or gas process, i.e. the doping element, for example arsenic, phosphorus, or antimony, is diffused from a source or charge of said doping element or a compound containing said doping element which is in vapour phase or solid phase.

For example, in a sealed bulb with two heating zones, a GaAs charge may be positioned in the hot portion and brought to a temperature for example of 550° C.; and the ZnO substrate may be positioned in the “cold” portion, for example at 500° C., for a time typically between 3 min and 2 hours, so as to induce the diffusion of arsenic from the thermal decomposition of the GaAs charge.

After the diffusion of the doping element, annealing, referred to as activation annealing, of the substrate wherein the dopant element has diffused may optionally be performed.

The conditions for this annealing, referred to as activation annealing of doping elements or species, may be easily determined by the man skilled in the art.

The activation annealing of the dopants of the substrate wherein the doping element has diffused may be performed at a temperature of 700° C. to 900° C. for 15 minutes to 2 hours in an oxygen atmosphere or air.

This activation annealing may also be performed by means of rapid thermal annealing (RTA) at a temperature generally between 700° C. and 800° C. and for a time between 10 and 300 seconds.

The invention will now be described with reference to the following examples, given for illustrative and not limiting purposes.

These examples make reference to the attached drawings, already described above.

### EXAMPLES

### Example 1

The graphs in FIGS. 1 and 2 represent secondary ion mass spectrometry (SIMS) measurements obtained on samples consisting of a ZnO substrate coated with a 250 nm thick silica layer, after various annealing processes at temperatures of 700° C. and 800° C. for times ranging from 5 hours to 15 hours. It is clear that the annealing processes induce exodiffusion of Zn to the silica and of phosphorus (FIG. 1) or arsenic (FIG. 2), these two types of diffusion increasing with the annealing temperature and with the annealing time. The exodiffusion of Zn to the silica corresponds to the formation of Zn vacancies in the ZnO substrate.

### Example 2

The image in FIG. 3 represents local capacitance measurements (in “scanning capacitance microscopy” (SCM) mode) of an atomic force microscope (AFM) of the top surface of ZnO nanowires encapsulated in p-doped SiO₂ and annealed at 800° C. for 5 hours (first embodiment).

These ZnO nanowires encapsulated in p-doped SiO₂ are nanowires prepared as follows:

ZnO nanowires between 1 and 5 μm in length, and between 100 and 300 nm in diameter were deposited by means of organometallic vapour phase epitaxy on sapphire substrates.

Non-doped silica deposition was performed by means of vapour phase deposition on all the nanowires, followed by a planarisation step after chemical mechanical polishing, and an etching step to reveal the top portion of the nanowires.

Finally, p-doped silica was deposited by means of vapour phase deposition on the surface thus prepared, followed by annealing at 800° C. for 30 minutes.

It is clear that the capacitance signal obtained indicates a p-type in the initially n-type nanowires, demonstrating that the method as described in the invention was implemented successfully.

### Example 3

FIG. 4 represents an electroluminescence curve of a set of ZnO nanowires, doped in the top portion thereof, by means of phosphorus diffusion from silica doped with this element, the bottom portion of the nanowires not being doped. The electroluminescence is indeed centred at 380 nm, as can be expected from a p/n ZnO homojunction. This is also a proof that the diffusion doping in the top portion of the nanowire is effective (first embodiment).

These ZnO nanowires are nanowires prepared as follows:

ZnO nanowires between 1 and 5 μm in length, and between 100 and 300 nm in diameter were deposited by means of organometallic vapour phase epitaxy on sapphire substrates.

Non-doped silica deposition was performed by means of vapour phase deposition on all the nanowires, followed by a planarisation step after chemical mechanical polishing, and an etching step to reveal the top portion of the nanowires.

Finally, p-doped silica was deposited by means of vapour phase deposition on the surface thus prepared, followed by annealing at 800° C. for 30 minutes.

### Example 4

The photograph of FIG. 5 shows the optical emission from a light-emitting diode having nanowires doped by means of diffusion in the top portion thereof.

These nanowires are nanowires prepared in the same way as in example 3.

1. A method for preparing p-type zinc oxide ZnO or p-type ZnMgO, comprising at least the sequence of the following two steps a) and b):
a) depositing silica, optionally doped with at least one doping element from column V of the periodic table of the elements, on a surface of an n-type ZnO or n-type ZnMgO substrate;
b) annealing the substrate and the deposited silica at a sufficient temperature and for a sufficient time to induce exodiffusion of zinc from the ZnO or ZnMgO substrate to the silica, and formation of zinc vacancies in at least one portion of the substrate adjacent to the silica; and
a step for doping said portion of the substrate adjacent to the silica and comprising the zinc vacancies with at least one doping element from column V of the periodic table of the elements during step b) or at the conclusion of step b).

2. The method according to claim 1, wherein the n-type ZnO or n-type ZnMgO substrate is in the form of a monolithic solid substrate.

3. The method according to claim 2, wherein the substrate is in the form of an heterostructure of ZnO quantum wells in ZnMgO alloy layers with a bottom layer of n-type doped ZnMgO and a top layer of non-doped ZnMgO on the top face whereof the silica is deposited.

4. The method according to claim 1, wherein the doping element from column V of the periodic table of the elements is selected from P, As and Sb.

5. The method according to claim 1, wherein the silica is deposited in the form of a layer.

6. The method according to claim 1, wherein during step b), annealing is performed at a temperature of 400° C. to 1000° C. for a time of 30 min to 15 hours.

7. The method according to claim 1, wherein said portion of the substrate adjacent to the silica extends over a thickness of 50 to 500 nm from an interface between the silica and ZnO or ZnMgO.

8. The method according to claim 1, wherein the doping of said portion of the substrate adjacent to the silica with at least one doping element from column V of the periodic table of the elements is performed by diffusion or by implantation of said element.

9. The method according to claim 1, wherein the following successive steps are performed:
depositing silica, doped with at least one doping element from column V of the periodic table of the elements, on a surface of an n-type ZnO or n-type ZnMgO substrate; and
annealing the substrate and the deposited silica at a sufficient temperature and for a sufficient time to induce exodiffusion of zinc from the ZnO or ZnMgO substrate to the silica, and formation of zinc vacancies in at least one portion of the substrate adjacent to silica; and simultaneously diffusing the doping element from column V of the periodic table of the elements to said portion of the substrate adjacent to the silica and comprising Zn vacancies.

10. The method according to claim 9, wherein annealing is performed at a temperature of 700° C. to 800° C., for a time of 30 min to 15 hours.

11. The method according to claim 1, wherein the following successive steps are performed:
depositing non-doped silica on a surface of an n-type ZnO or n-type ZnMgO substrate;
annealing the substrate and deposited silica at a sufficient temperature and for a sufficient time to induce exodiffusion of zinc from the ZnO or ZnMgO substrate to the silica, and the formation of zinc vacancies in at least one portion of the substrate adjacent to the silica;
implanting at least one doping element from column V of the periodic table of the elements through the silica in said portion of the substrate adjacent to the silica and comprising zinc vacancies; and
annealing the substrate implanted with doping elements to remove the implantation defects and activate the doping elements.

12. The method according to claim 11, wherein implantation is performed at room temperature, for a total implanted dose between 10^{E}13 and 10^{E}15 at/cm², and an energy between 50 and 200 keV.

13. The method according to claim 11, wherein annealing is performed at a temperature of 700° C. to 900° C., for a time of 15 min to 2 hours.

14. The method according to claim 1, wherein the following successive steps are performed:
depositing non-doped silica on a surface of an n-type ZnO or n-type ZnMgO substrate;
annealing the substrate and the deposited silica at a sufficient temperature and for a sufficient time to induce exodiffusion of zinc from the ZnO or ZnMgO substrate to the silica, and the formation of zinc vacancies in at least one portion of the substrate adjacent to the silica;
removing the silica;
diffusing at least one doping element from column V of the periodic table of the elements in said portion of the substrate adjacent to the silica and comprising zinc vacancies; and
optionally annealing to activate the dopants in the substrate wherein the doping element has diffused.

15. The method according to claim 14, wherein the silica is removed by means of a reactive ion etching (RIE) method or by means of a chemical etching method.

16. The method according to claim 14, wherein the diffusion of at least doping element from column V of the periodic table of the elements is performed using a solid or vapour source of said doping element or of a compound containing said doping element.

17. The method according to claim 14, wherein the optional activation annealing of the dopants in the substrate wherein the dopant elements has diffused is performed by means of a treatment at a temperature of 700° C. to 900° C. for a time of 15 min to 2 hours; or by means of rapid thermal annealing (RTA) at a temperature of 700° C. to 800° C. and for a time of 10 to 300 seconds.

18. The method according to claim 2, wherein the n-type ZnO or n-type ZnMgO substrate is in the form of a layer, of at least one nanowire, or of a heterostructure of ZnO quantum wells.

19. The method according to claim 18, wherein the layer is an epitaxial layer.

20. The method according to claim 5, wherein a thickness of the deposited silica layer is from 50 to 500 nm.

21. The method according to claim 5, wherein a thickness of the deposited silica layer is from 100 to 500 nm.

22. The method according to claim 6, wherein during step b), annealing is performed at a temperature of 600° C. to 950° C. for a time of 30 min to 15 hours.

23. The method according to claim 6, wherein during step b), annealing is performed at a temperature of 700° C. to 800° C., for a time of 30 min to 15 hours.

24. The method according to claim 10, wherein annealing is performed in an oxygen atmosphere or air.

25. The method according to claim 13, wherein annealing is performed in an oxygen atmosphere or air.

26. The method according to claim 16, wherein said at least doping element comprises arsenic or phosphorus.

27. The method according to claim 17, wherein the optional activation annealing of the dopants in the substrate wherein the dopant elements has diffused is performed by means of a treatment at a temperature of 700° C. to 900° C. for a time of 15 min to 2 hours, in an oxygen atmosphere or air.
